(19) United States
(12) Patent Application Publication
(10) Pub. No.: US 2017/0025578 A1
(43) Pub. Date: Jan. 26, 2017

(54) NITRIDE SEMICONDUCTOR ELEMENT

(71) Applicant: Kabushiki Kaisha Toshiba, Minato-ku (JP)

(72) Inventors: Toshiki HIKOSAKA, Kawasaki (JP); Hisashi Yoshida, Kawasaki (JP); Kenjiro Uesugi, Kawasaki (JP); Hiroshi Ono, Setagaya (JP); Shinya Nunoue, Ichikawa (JP)

(73) Assignee: Kabushiki Kaisha Toshiba, Minato-ku (JP)

(21) Appl. No.: 15/053,266

(22) Filed: Feb. 25, 2016

(30) Foreign Application Priority Data
Jul. 21, 2015 (JP) 2015-143761

(51) Int. Cl. H01L 33/32; H01L 33/38; H01L 33/22; H01L 33/18; H01L 33/24

(52) U.S. Cl. CPC H01L 33/32; H01L 33/18; H01L 33/24; H01L 33/22; H01L 33/38

(57) ABSTRACT

According to one embodiment, a nitride semiconductor element includes a p-type semiconductor layer and a p-side electrode. The p-type semiconductor layer includes a nitride semiconductor, and has a first surface. The p-side electrode contacts the first surface. The first surface is a semi-polar plane. The first surface includes a plurality of protrusions. A height of the protrusions along a first direction is not less than 1 nanometer and not more than 5 nanometers. The first direction is from the p-type semiconductor layer toward the p-side electrode. A density of the protrusions in the first surface is more than 1.0×10¹⁰/cm² and not more than 6.1×10¹⁰/cm².

### CROSS-REFERENCE TO RELATED APPLICATIONS

This application is based upon and claims the benefit of priority from Japanese Patent Application No. 2015-143761, filed on Jul. 21, 2015; the entire contents of which are incorporated herein by reference.

### FIELD

Embodiments described herein relate generally to a nitride semiconductor element.

### BACKGROUND

For example, a light emitting diode (LED), which is one type of nitride semiconductor element, is used in display devices, illumination, etc. Nitride semiconductor elements also include high-speed electronic devices and power devices. It is desirable to reduce the drive voltage of such nitride semiconductor elements.

### BRIEF DESCRIPTION OF THE DRAWINGS

FIG. 1 is a schematic cross-sectional view showing the nitride semiconductor element according to a first embodiment;

FIG. 2A to FIG. 2C are atomic force microscope images showing the nitride semiconductor element;

FIG. 3A and FIG. 3B are schematic views showing the nitride semiconductor element;

FIG. 4A and FIG. 4B are schematic views showing the nitride semiconductor element;

FIG. 5 is a graph of a characteristic of the nitride semiconductor element;

FIG. 6 is a graph of a characteristic of the nitride semiconductor element according to the first embodiment;

FIG. 7A and FIG. 7B are graphs of characteristics of the nitride semiconductor element;

FIG. 8A and FIG. 8B are graphs of characteristics of the nitride semiconductor element; and

FIG. 9A to FIG. 9F are schematic views showing the nitride semiconductor element.

### DETAILED DESCRIPTION

According to one embodiment, a nitride semiconductor element includes a p-type semiconductor layer and a p-side electrode. The p-type semiconductor layer includes a nitride semiconductor, and has a first surface. The p-side electrode contacts the first surface. The first surface is a semi-polar plane. The first surface includes a plurality of protrusions. A height of the protrusions along a first direction is not less than 1 nanometer and not more than 5 nanometers. The first direction is from the p-type semiconductor layer toward the p-side electrode. A density of the protrusions in the first surface is more than 1.0×10¹⁰/cm² and not more than 6.1×10¹⁰/cm².

Various embodiments will be described hereinafter with reference to the accompanying drawings.

The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

In the drawings and the specification of the application, components similar to those described in regard to a drawing thereinabove are marked with like reference numerals, and a detailed description is omitted as appropriate.

### First Embodiment

The embodiment relates to a nitride semiconductor element. The nitride semiconductor element according to the embodiment includes semiconductor devices such as semiconductor light emitting elements, semiconductor light receiving elements, electronic devices, etc. The semiconductor light emitting elements include, for example, light emitting diodes (LEDs), laser diodes (LDs), etc. The semiconductor light receiving elements include photodiodes (PDs), etc. The electronic devices include, for example, high electron mobility transistors (HEMTs), heterojunction bipolar transistors (HBTs), field effect transistors (FETs), Schottky barrier diodes (SBDs), etc.

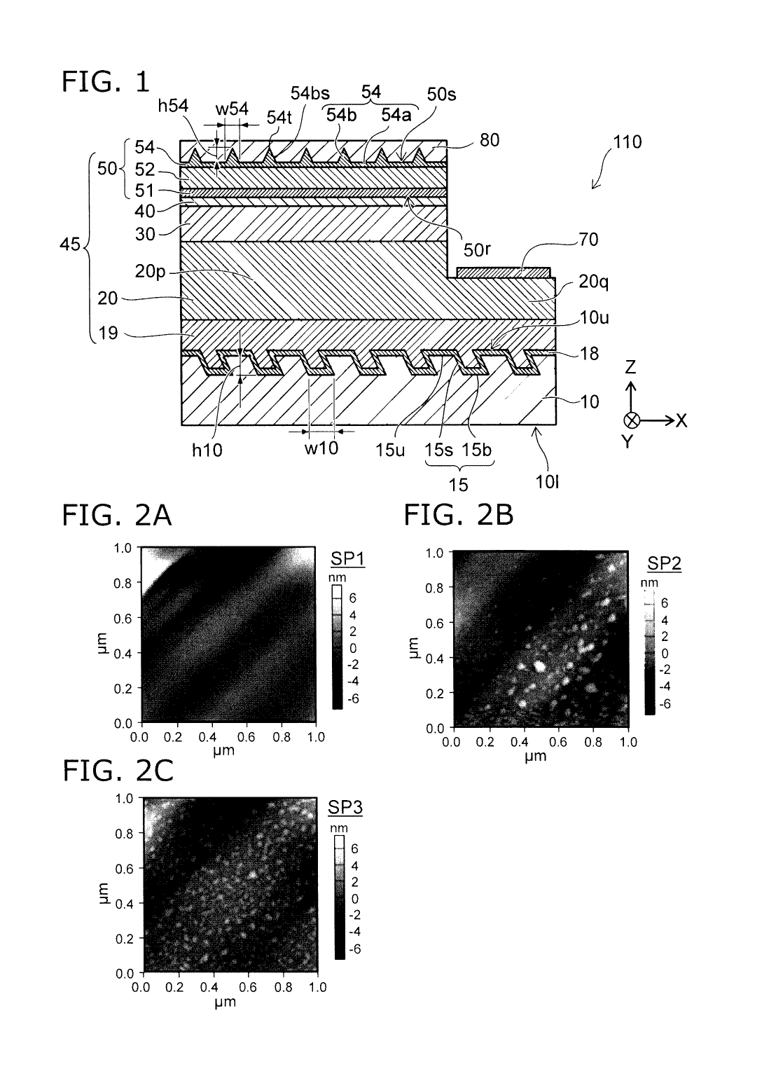

FIG. 1 is a schematic cross-sectional view showing the nitride semiconductor element according to the first embodiment.

As shown in FIG. 1, the nitride semiconductor element 110 according to the embodiment includes a p-type semiconductor layer 50 and a p-side electrode 80. In the example, the nitride semiconductor element 110 further includes an n-type semiconductor layer 20 and a light emitting layer 40. The nitride semiconductor element is a semiconductor light emitting element.

The p-type semiconductor layer 50 is provided between the n-type semiconductor layer 20 and the p-side electrode 80. The light emitting layer 40 is provided between the n-type semiconductor layer 20 and the p-type semiconductor layer 50.

A direction from the p-type semiconductor layer 50 toward the p-side electrode 80 is taken as a first direction (a Z-axis direction). One direction perpendicular to the Z-axis direction is taken as an X-axis direction. A direction perpendicular to the Z-axis direction and the X-axis direction is taken as a Y-axis direction.

In the example, the nitride semiconductor element 110 includes a substrate 10, a buffer layer 18, a foundation layer 19, a stacked body 30, and an n-side electrode 70. The buffer layer 18 is provided on the substrate 10. The foundation layer 19 is provided on the buffer layer 18. The n-type semiconductor layer 20 is provided on the foundation layer 19. The stacked body 30 is provided on a first portion 20p of the n-type semiconductor layer 20. The n-side electrode 70 is provided on a second portion 20q of the n-type semiconductor layer 20. The stacked body 30 is provided on the first portion 20p. The light emitting layer 40 is provided on the stacked body 30. The p-type semiconductor layer 50 is provided on the light emitting layer 40. The p-side electrode 80 is provided on the p-type semiconductor layer 50. The direction from the first portion 20p toward the second portion 20q intersects the direction (the Z-axis direction) from the p-type semiconductor layer 50 toward the p-side electrode 80.

In the specification of the application, the state in which a first component is provided on a second component includes the state in which the first component contacts the second component and the state in which a third component is provided between the first component and the second component.

The p-type semiconductor layer 50, the light emitting layer 40, the stacked body 30, and the n-type semiconductor layer 20 each include a nitride semiconductor.

The p-type semiconductor layer 50 contacts the p-side electrode 80. For example, the p-type semiconductor layer 50 includes a p-type contact layer 54. The p-side electrode 80 contacts the p-type contact layer 54. The p-side electrode 80 is electrically connected to the p-type semiconductor layer 50 (the p-type contact layer 54).

In the example, the p-type semiconductor layer 50 further includes a first p-type layer 51 and a second p-type layer 52. The first p-type layer 51 is provided between the p-type contact layer 54 and the light emitting layer 40. The second p-type layer 52 is provided between the p-type contact layer 54 and the first p-type layer 51.

The first p-type layer 51 includes, for example, an AlGaN layer including a p-type impurity. The p-type impurity is, for example, Mg. For example, the first p-type layer 51 functions as an electron overflow suppression layer (an electron overflow prevention layer). The thickness of the first p-type layer 51 is, for example, not less than 3 nm and not more than 30 nm, e.g., 10 nm. The p-type impurity concentration of the first p-type layer 51 is, for example, not less than 1×10¹⁹/cm³ and not more than 5×10²⁰/cm³, e.g., 1×10²⁰/cm³. The Al composition ratio x of the AlₓGa₁₋ₓN layer of the first p-type layer 51 is not less than 0.05 and not more than 0.3, e.g., 0.1.

The second p-type layer 52 includes, for example, a GaN layer including a p-type impurity. The p-type impurity is, for example, Mg. The thickness of the second p-type layer 52 is, for example, not less than 50 nm and not more than 200 nm, e.g., 100 nm. The p-type impurity concentration of the second p-type layer 52 is, for example, not less than 5×10¹⁸/cm³ and not more than 5×10²⁰/cm³, e.g., 6×10¹⁹/cm³. For example, the p-type impurity concentration of the second p-type layer 52 is lower than the p-type impurity concentration of the first p-type layer 51.

The p-type contact layer 54 includes, for example, a GaN layer including a p-type impurity. The p-type impurity is, for example, Mg. For example, the p-type impurity concentration of the p-type contact layer 54 is higher than the p-type impurity concentration included in the second p-type layer 52. The thickness of the p-type contact layer 54 is, for example, not less than 1 nm and not more than 50 nm. It is more favorable for the thickness of the p-type contact layer 54 to be not less than 3 nm and not more than 30 nm. The p-type impurity concentration of the p-type contact layer 54 is not less than 2×10¹⁹/cm³ and not more than 1×10²²/cm³. For example, the region of the p-type semiconductor layer 50 that contacts the p-side electrode 80 and has a p-type impurity concentration that is higher than that of the second p-type layer 52 corresponds to the p-type contact layer 54. For example, the p-type contact layer 54 functions as a contact layer on the p-side.

For example, Mg (magnesium) is used as the p-type impurity. Other than Mg, C (carbon), Zn (zinc), and Be (beryllium) may be used as the p-type impurity.

The p-type contact layer 54 may be discontinuous. The p-type contact layer 54 may have an island configuration. The p-type contact layer 54 may have a mesh configuration. The p-type contact layer 54 may have openings. The p-type contact layer 54 is called a “layer” even in the case where the p-type contact layer 54 is discontinuous. In the case where the p-type contact layer 54 is discontinuous, a portion of the second p-type layer 52 may contact the p-side electrode 80.

In the embodiment, the first p-type layer 51 and the second p-type layer 52 are provided as necessary.

The n-type semiconductor layer 20 includes, for example, a GaN layer including an n-type impurity. For example, Si (silicon) is used as the n-type impurity. The thickness of the n-type semiconductor layer 20 is, for example, not less than 500 nm and not more than 10 μm. The impurity concentration of the n-type semiconductor layer 20 is not less than 5×10¹⁷/cm³ and not more than 5×10¹⁹/cm³. For example, the n-type semiconductor layer 20 functions as a contact layer on the n-side.

The stacked body 30 includes multiple first layers (not shown) and multiple second layers (not shown) stacked alternately. The first layer is, for example, a GaN layer; and the thickness of the first layer is, for example, about 3 nanometers (nm) (e.g., not less than 2 nm and not more than 4 nm). The second layer is, for example, an InGaN layer. The thickness of the second layer is, for example, about 1 nm (e.g., not less than 0.5 nm and not more than 2 nm). The number of first layers is, for example, 21 layers; and the number of second layers is, for example, 20 layers. The stacked body 30 is, for example, a superlattice layer.

The light emitting layer 40 includes multiple barrier layers (not shown), and a well layer (not shown) provided between the multiple barrier layers. The number of well layers may be one. The number of well layers may be two or more. The multiple barrier layers and the multiple well layers are provided alternately. The light emitting layer 40 has a single quantum well (SQW) structure or a multiple quantum well (MQW) structure.

The barrier layer includes, for example, an undoped GaN layer. The thickness of the barrier layer is, for example, not less than 3 nm and not more than 20 nm, e.g., about 5 nm. The well layer includes, for example, an undoped In_{0.15}Ga_{0.85}N layer. The thickness of the well layer is, for example, not less than 1.5 nm and not more than 20 nm, e.g., about 2.5 nm. In the embodiment, the materials and thicknesses of the barrier layer and the well layer are arbitrary.

The barrier layer and the well layer include nitride semiconductors. The well layer includes a nitride semiconductor including indium (In). The bandgap energy of the barrier layer is larger than the bandgap energy of the well layer. For example, in the case where the barrier layer includes In, the concentration of In of the barrier layer is lower than the concentration of In of the well layer.

The barrier layer and the well layer are designed so that the wavelength of the light emitted from the light emitting layer 40 has a desired value. The peak wavelength of the light emitted from the light emitting layer 40 is, for example, not less than 380 nm and not more than 650 nm. The intensity of the light emitted from the light emitting layer 40 is highest at the peak wavelength. For example, the wavelength of the photoluminescence of the light emitting layer 40 at room temperature is not less than 380 nm and not more than 650 nm, e.g., about 450 nm.

The n-side electrode 70 contacts the n-type semiconductor layer 20. The n-side electrode 70 includes, for example, a composite film of aluminum/tantalum/titanium/aluminum/titanium (Al/Ta/Ti/Al/Ti). For example, the thicknesses respectively are about 100 nm/50 nm/50 nm/1000 nm/50 nm.

The p-side electrode 80 includes, for example, at least one of a metal or a conductive metal compound. The conductive metal compound includes, for example, indium tin oxide (ITO), etc. When the p-side electrode 80 includes ITO, the thickness of the p-side electrode 80 is, for example, about 0.25 micrometers (μm) (e.g., not less than 0.1 μm and not more than 0.3 μm). The metal that is included in the p-side electrode 80 includes, for example, a composite film of nickel/silver (Ni/Ag), etc. The p-side electrode 80 includes, for example, a metal film including Ag. A metal layer that is used to form a pad electrode may be provided on the p-side electrode 80.

A voltage is applied between the n-side electrode 70 and the p-side electrode 80. A current flows in the light emitting layer 40 via the n-type semiconductor layer 20 and the p-type semiconductor layer 50; and light is emitted from the light emitting layer 40.

In the nitride semiconductor element 110, a functional layer 45 is provided on the substrate 10. The functional layer 45 includes the n-type semiconductor layer 20, the light emitting layer 40, and the p-type semiconductor layer 50. In the example, the functional layer 45 includes the stacked body 30. The functional layer 45 includes a nitride semiconductor. The functional layer 45 includes a semiconductor crystal.

The substrate 10 has an upper surface 10u and a lower surface 10l. The lower surface 10l is the surface on the side opposite to the upper surface 10u. The functional layer 45 is provided on the upper surface 10u. The upper surface 10u opposes the functional layer 45.

The substrate 10 is a substrate for crystal growth. For example, the buffer layer 18 is formed on the substrate 10; the foundation layer 19 is formed on the buffer layer 18; and the functional layer 45 is formed on the foundation layer 19. The substrate 10 may be removed after the functional layer 45 is formed. At least a portion of the buffer layer 18 may be removed at this time. At least a portion of the foundation layer 19 also may be removed.

The n-type semiconductor layer 20 may be disposed between the n-side electrode 70 and the light emitting layer 40 in the state in which the substrate 10 is removed. For example, at least a portion of the n-side electrode 70 and at least a portion of the p-side electrode 80 may overlap in the Z-axis direction.

The substrate 10 includes, for example, silicon. The buffer layer 18 includes, for example, a non-doped AlN layer. The thickness of the buffer layer 18 is, for example, about 100 nm (e.g., not less than 70 nm and not more than 130 nm). The foundation layer 19 includes, for example, a non-doped GaN layer. The thickness of the foundation layer 19 is, for example, not less than 500 nm and not more than 1000 μm. The concentration of the impurity included in the buffer layer 18 and the foundation layer 19 is lower than the concentration of the n-type impurity included in the n-type semiconductor layer 20. The concentration of the n-type impurity included in the buffer layer 18 and the foundation layer 19 is, for example, 5×10¹⁷/cm³ or less. The concentration of the n-type impurity included in the buffer layer 18 and the foundation layer 19 may be, for example, 1×10¹⁶/cm³ (e.g., the detection limit) or more. The n-type impurity is, for example, Si.

For example, the impurity concentration can be measured by SIMS analysis.

The substrate 10 is, for example, a silicon substrate of the {113} plane. The upper surface 10u of the substrate 10 has multiple recesses 15 (trenches). As described below, the multiple recesses 15 extend along a direction perpendicular to the c-axis direction of the functional layer 45 (e.g., the n-type semiconductor layer 20).

The substrate 10 may be a sapphire substrate of the r-plane (the {1-102} plane). The multiple recesses 15 are provided in the r-plane of the sapphire substrate.

The multiple recesses 15 are made by removing a portion of the front surface of the base body used to form the substrate 10. The portion of the upper surface 10u of the substrate 10 other than the multiple recesses 15 is a top surface 15u. The upper surface 10u includes the top surface 15u and the multiple recesses 15. The recess 15 includes a bottom surface 15b and a side surface 15s. A depth h10 of the recess 15 is the difference in the Z-axis direction of the position in the Z-axis direction of the top surface 15u and the position in the Z-axis direction of a bottom 16b. One recess 15 includes two side surfaces 15s. The two side surfaces 15s oppose each other in a direction perpendicular to the extension direction of the recess 15. A width w10 of the recess 15 is the spacing between the two side surfaces 15s in a direction that is perpendicular to the extension direction of the recess 15 and perpendicular to the Z-axis direction.

The buffer layer 18 covers the upper surface 10u. For example, the buffer layer 18 contacts the side surface 15s of the recess 15. A portion of the buffer layer 18 covers the top surface 15u. The buffer layer 18 may be separated from the bottom surface 15b. The foundation layer 19 covers the buffer layer 18. For example, the foundation layer 19 contacts the portion of the buffer layer 18 contacting the side surface 15s of the recess 15. The portion of the foundation layer 19 overlapping the bottom surface 15b in the Z-axis direction may be separated from the buffer layer 18. The portion of the foundation layer 19 overlapping the top surface 15u in the Z-axis direction may be separated from the buffer layer 18.

The p-type semiconductor layer 50 has a first surface 50s and a second surface 50r. The second surface 50r is a surface on the side opposite to the first surface 50s. The p-side electrode 80 contacts the first surface 50s. The second surface 50r opposes the light emitting layer 40.

The first surface 50s of the p-type semiconductor layer 50 is a semi-polar plane. For example, the semi-polar plane is tilted from the c-plane (i.e., the {0001} plane). The angle between the semi-polar plane and the c-plane is more than 0 degrees and less than 90 degrees. Or, the angle between the semi-polar plane and the c-plane is more than 90 degrees and less than 180 degrees. For example, the semi-polar plane is tilted at a small angle from the c-plane. For example, the first surface 50s is the {11-22} plane of the p-type semiconductor layer 50. In the embodiment, the first surface 50s may be tilted a small angle with respect to the {11-22} plane. For example, the angle between the first surface 50s and the {11-22} plane of the p-type semiconductor layer 50 is 5 degrees or less.

Other than the {11-22} plane, the semi-polar plane may be the {10-11} plane, the {20-21} plane, the {10-12} plane, the {10-13} plane, etc. For example, the angle between the first surface 50s and the crystal plane (the semi-polar plane) of the p-type semiconductor layer 50 recited above is 5 degrees or less.

In the embodiment, the first surface 50s includes multiple protrusions 54b. For example, a height h54 of the multiple protrusions 54b (the height of one of the multiple protrusions 54b) along the Z-axis direction (the first direction from the p-type semiconductor layer 50 toward the p-side electrode 80) is, for example, 5 nm or less. The height h54 is, for example, 1 nm or more.

For example, the density in the first surface 50s of the multiple protrusions 54b is higher than 1.0×10¹⁰/cm². The density is, for example, 6.1×10¹⁰/cm² or less. It is more favorable for the density in the first surface 50s of the multiple protrusions 54b to be not less than 1.5×10¹⁰/cm² and not more than 5.2×10¹⁰/cm².

A width w54 of the multiple protrusions 54b (the width of one of the multiple protrusions 54b) is 10 nm or more. The width w54 is 100 nm or less. The width w54 is the length of one of the multiple protrusions 54b in a direction (e.g., the X-axis direction) perpendicular to the Z-axis direction (the first direction).

For example, the p-type contact layer 54 may include a bottom 54a. The height of the multiple protrusions 54b is the distance along the Z-axis direction between the bottom 54a and an apical portion 54t of the protrusion 54b.

The width of one of the multiple protrusions 54b is the maximum value of the length along the X-axis direction of the one of the multiple protrusions 54b.

The multiple protrusions 54b includes the apical portion 54t and a side surface 54bs. The apical portion 54t is the portion of the p-type contact layer 54 where the distance to the light emitting layer 40 is the longest. The side surface 54bs intersects the X-Y plane.

When one protrusion 54b is cut by a plane including the Z-axis direction and including the apical portion 54t of the one protrusion 54b, the one protrusion 54b is provided between two bottoms 54a. The width w54 of the one protrusion 54b is the distance between the two bottoms 54a.

Each of the multiple protrusions 54b protrudes from the bottom 54a toward the p-side electrode 80. The p-side electrode 80 is provided around the side surface 54bs of the protrusion 54b. The p-side electrode 80 is provided around the apical portion 54t of the protrusion 54b.

In the embodiment, the contact resistance between the p-side electrode 80 and the first surface 50s of the p-type semiconductor layer 50 can be reduced by providing such protrusions 54b. Thereby, the nitride semiconductor element 110 that has a low drive voltage can be provided.

The inventor discovered by independent experiments that the drive voltage can be reduced by providing the protrusions 54b. The experiments will now be described. The samples that were made and the evaluation results of the samples will now be described.

The multiple recesses 15 are provided in the upper surface 10u of the substrate 10.

For example, the base body that is used to form the substrate 10 includes a silicon substrate of the {113} plane. The orientation of the orientation flat of the silicon substrate is, for example, the <−110> direction. A silicon dioxide film that is used to form a mask layer is formed on the silicon substrate. The silicon dioxide film is, for example, a thermal oxide film. The thickness of the silicon dioxide film is, for example, about 100 nm (e.g., not less than 60 nm and not more than 140 nm). A resist film having a prescribed configuration is formed on the silicon dioxide film. The configuration of the resist film is, for example, a stripe configuration.

The width of the resist film (the length in a direction orthogonal to the extension direction of the stripes) is, for example, not less than 0.5 μm and not more than 15 μm, e.g., about 3 μm. The width of the openings (the spacing between the multiple stripes) of the resist film is, for example, not less than 0.5 μm and not more than 5 μm, e.g., about 7 μm. The period of the stripes is, for example, not less than 1 μm and not more than 20 μm, e.g., about 10 μm.

The silicon dioxide film is exposed at the openings of the resist film. A portion of the silicon dioxide film is removed using the resist film as a mask. In other words, the silicon dioxide film that is exposed from the openings is removed. For example, the removal is performed by etching using buffered hydrofluoric acid. O₂ asher processing may be performed prior to the removal. Thereby, the hydrophilic property improves; and the uniformity of the etching increases. The resist film is removed after removing the portion of the silicon dioxide film. Thereby, the mask layer is formed. The patterning may be performed using dry etching.

A portion of the substrate (in the example, the silicon substrate) is removed using the mask layer as a mask. In other words, a portion of the base body that is exposed from the mask layer is removed. The substrate 10 is obtained by patterning the base body. For example, multiple recesses 15 having stripe configurations are made in the base body. The depth h10 of the recess 15 is, for example, not less than 100 nm and not more than 2000 nm. For example, the patterning is performed by processing using a potassium hydroxide (KOH) solution (25 wt % and 45° C.) for, for example, 5 minutes. Thereby, the recess 15 is made. The depth h10 of the recess 15 is, for example, about 500 nm. The side surface 15s of the recess 15 is tilted with respect to the Z-axis direction due to the anisotropy of the etching rate of the silicon. The side surface 15s is, for example, an oblique surface. In the case where silicon is etched using a KOH solution, the etching rate of the (111) plane is slow compared to the other crystal planes. Therefore, the side surface 15s becomes an oblique surface easily because the (111) plane of the silicon becomes the side surface 15s easily. The patterning may be performed by forming the oblique surface (the side surface 15s) using dry etching.

In the embodiment, for example, the depth h10 of the recess 15 is less than the width w10 of the recess 15. By setting the depth h10 to be less than the width w10, for example, the crystal growth from the side surface 15s is easy. By setting the depth h10 to be less than the width w10, for example, the defect density of the nitride crystal (e.g., the foundation layer 19) is reduced easily.

Thereby, the substrate 10 shown in FIG. 1 is obtained. The multiple recesses 15 are provided in the upper surface 10u of the substrate 10. The side surface 15s of each of the multiple recesses 15 is tilted with respect to the Z-axis direction.

At least a portion of the side surface 15s (the side wall) of the recess 15 is used to form the (1-11) plane of the silicon. The side surface 15s (the oblique surface) is tilted with respect to the (113) plane of the upper surface 10u of the substrate 10. The angle between the side surface 15s (the oblique surface) and the (113) plane is about 58.5 degrees. The nitride crystal grows from the side surface 15s (the (1-11) plane which is an oblique surface).

In the embodiment, at least a portion of the side surface 15s (the side wall) is, for example, a crystal plane that is equivalent to the (111) plane. At least a portion of the side surface 15s (the side wall) is, for example, a crystal plane expressed by the inclusive expression of the {111} plane using Miller indexes. For example, at least a portion of the side surface 15s (the side wall) may be the (1-11) plane, the (11-1) plane, or the (−11-1) plane. By forming the crystal plane that is equivalent to the (111) plane in the substrate 10, the crystal growth of the nitride crystal (e.g., the functional layer 45, etc.) is easy.

The buffer layer 18 is formed on the upper surface 10u of the substrate 10. At this time, for example, the buffer layer 18 grows from the side surface 15s of the recess 15 of the upper surface 10u of the substrate 10. The buffer layer 18 covers the top surface 15u. The buffer layer 18 covers the upper surface 10u of the substrate 10. The foundation layer 19 is formed on the buffer layer 18. The functional layer 45 (the n-type semiconductor layer 20, the stacked body 30, the light emitting layer 40, and the p-type semiconductor layer 50) is formed on the foundation layer 19. In other words, epitaxial growth is performed.

An example of the epitaxial growth is described below.

For example, the substrate 10 in which the recesses 15 are made is processed by organic cleaning and acid cleaning. Subsequently, the substrate 10 is introduced to the reactor of a MOCVD apparatus. An AlN layer that is used to form the buffer layer 18 is formed using tri-methyl aluminum (TMAl) and ammonia (NH₃) in a hydrogen atmosphere (e.g., a hydrogen-containing atmosphere). The thickness of the buffer layer 18 is about 100 nm. At this time, the growth temperature (the substrate temperature) is about 1060° C.; the growth pressure is 200 hPa; and the V/III ratio is 150.

Subsequently, an undoped GaN layer that is used to form the foundation layer 19 is grown using TMGa and ammonia in an atmosphere including nitrogen and hydrogen. At this time, the growth temperature is about 1060° C.; the growth pressure is 600 hPa; and the V/III ratio is 3300. The undoped GaN layer grows from the side surface 15s (the (1-11) plane, i.e., the oblique surface) of the recess 15 of the substrate 10.

Thereby, the foundation layer 19 (the GaN crystal) having the tilted crystal orientation is obtained. In the foundation layer 19, the c-axis is tilted with respect to the Z-axis direction (a direction perpendicular to the upper surface 10u of the substrate 10). The angle between the Z-axis direction and the c-axis of the foundation layer 19 is about 58.5 degrees. Thus, the GaN crystal is obtained in which the c-axis is tilted about 58.5 degrees from the Z-axis direction. In other words, the angle between the upper surface 10u and the c-axis of the foundation layer 19 (the GaN layer) is about 31.5 degrees.

In the initial growth of the undoped GaN layer used to form the foundation layer 19, the undoped GaN layer is a crystal having a stripe configuration. The mutually-adjacent crystals having the stripe configuration meet as the growth time increases. Thereby, the major surface (the front surface) of the undoped GaN layer becomes the {11-22} plane. The foundation layer 19 is formed by further continuing the crystal growth. The thickness of the foundation layer 19 is, for example, about 3 μm.

Continuing, an n-type GaN layer that is used to form the n-type semiconductor layer 20 (the n-type contact layer) is formed by using TMG, NH₃, and silane (SiH₄) at 1030° C. in a carrier gas of nitrogen and hydrogen. The thickness of the n-type semiconductor layer 20 is about 2 μm. The n-type impurity is Si. The SiH₄ is used as the source material of the n-type impurity. The Si concentration of the n-type GaN layer is 5×10¹⁸/cm³.

Then, the stacked body 30 is formed. Namely, an n-type GaN layer is formed using TMG, NH₃, and SiH₄ in a nitrogen atmosphere at 800° C.; continuing, an undoped In_{0.07}Ga_{0.93}N layer is formed using TMG, trimethylindium (TMI), and NH₃ at 800° C. The n-type GaN layer is used to form the first layer. The thickness of the first layer is about 3 nm. The undoped In_{0.07}Ga_{0.93}N layer is used to form the second layer. The thickness of the second layer is about 1 nm. Subsequently, the formation of the first layer and the formation of the second layer recited above are repeated. The number of formations of the first layer is 20; and the number of formations of the second layer is 20. Finally, the first layer is further formed. Thereby, the stacked body 30 is formed. The Si concentration of the n-type GaN layer in the stacked body 30 is 2×10¹⁸/cm³.

Then, the light emitting layer 40 is formed. Namely, an undoped GaN layer that is used to form a barrier layer is formed using TMG and NH₃ in a nitrogen atmosphere. The thickness of the barrier layer is about 5 nm. Continuing, an undoped In_{0.15}Ga_{0.85}N layer that is used to form a well layer is formed using TMG, TMI, and NH₃. The thickness of the well layer is about 2.5 nm. The formation of the barrier layer and the formation of the well layer recited above are repeated. The number of formations of the barrier layer is 3; and the number of formations of the well layer is 3. Finally, the barrier layer is further formed. Thereby, the light emitting layer 40 is formed.

Then, a p-type AlₓGa₁₋ₓN layer that is used to form the first p-type layer 51 is formed using TMA, TMG, NH₃, and bis(cyclopentadienyl)magnesium (Cp₂Mg) in an atmosphere including nitrogen and hydrogen. At this time, the growth temperature is about 900° C.; the growth pressure is 1013 hPa; and the V/III ratio is 10000. The Cp₂Mg is used as the source material of the p-type impurity. The thickness of the first p-type layer 51 is about 5 nm. The Al composition ratio x of the AlₓGa₁₋ₓN layer is 0.1.

Continuing, a p-type GaN layer that is used to form the second p-type layer 52 is formed using TMG, NH₃, and Cp₂Mg in an atmosphere including nitrogen and hydrogen. The thickness of the second p-type layer 52 is about 80 nm. At this time, the growth temperature (the substrate temperature) is 900° C.; the growth pressure is 1013 hPa; and the V/III ratio is 1600.

Then, a p-type GaN layer that is used to form the p-type contact layer 54 is formed by changing the supply ratio of nitrogen, hydrogen, and ammonia and increasing the supply amount of Cp₂Mg. The average of the thickness of the p-type contact layer 54 is about 5 nm. At this time, the growth temperature (the substrate temperature) is 880° C.; the growth pressure is 1013 hPa; and the V/III ratio is 8500. The growth rate is about 1 nm/minute.

The p-type contact layer 54 includes the bottoms 54a and the protrusions 54b. The thickness of the bottoms 54a is, for example, about 4 nm; and the height of the protrusions 54b is about 5 nm. Considering the density of the protrusions 54b, the average thickness of the p-type contact layer 54 when the thicknesses of the bottoms 54a and the protrusions 54b are summed and averaged is about 5 nm.

After the crystal growth recited above, the temperature is reduced to room temperature.

The front surface of a portion of the n-type semiconductor layer 20 is exposed by using dry etching to remove a portion of the semiconductor stacked body obtained as recited above. A stacked film of Al/Ta/Ti/Al/Ti that is used to form the n-side electrode 70 is formed on the exposed n-type semiconductor layer 20. A Ag film that is used to form the p-side electrode 80 is formed on the p-type contact layer 54.

Thereby, the nitride semiconductor element 110 (the semiconductor light emitting element) is obtained.

Multiple samples are made in the experiments. For these samples, the formation conditions are modified for the p-type GaN layer used to form the p-type contact layer 54. The surface state (the state of the first surface 50s) of the p-type contact layer 54 and the drive voltage are evaluated.

FIG. 2A to FIG. 2C are atomic force microscope images showing the nitride semiconductor element.

FIG. 2A to FIG. 2C are atomic force microscope (AFM) images of the front surface of the p-type GaN layer used to form the p-type contact layer 54. These images show square regions having sides of 1 μm. The height scale is 15 nm.

FIG. 2A to FIG. 2C correspond to three types of samples (a first sample SP1, a second sample SP2, and a third sample SP3). The formation conditions of the p-type GaN layer used to form the p-type contact layer 54 are different between these samples. In other words, the supply amount of the p-type impurity in the formation of the p-type GaN layer used to form the p-type contact layer 54 is modified. The supply amount (a second supply amount) of the p-type impurity of the second sample SP2 is 4 times the supply amount (a first supply amount) of the p-type impurity of the first sample SP1. The supply amount (a third supply amount) of the p-type impurity of the third sample SP3 is 6 times the first supply amount. The p-type impurity is Mg.

As shown in FIG. 2A, the protrusions 54b are not formed in the p-type contact layer 54 of the first sample SP1 having the first supply amount.

As shown in FIG. 2B, the protrusions 54b are formed in the p-type contact layer 54 of the second sample SP2 having the second supply amount having the large supply amount of the p-type impurity. The protrusions 54b have truncated polygonal pyramid configurations.

As shown in FIG. 2C, even more protrusions 54b are formed in the third sample SP3 having the third supply amount having the even larger supply amount of the p-type impurity.

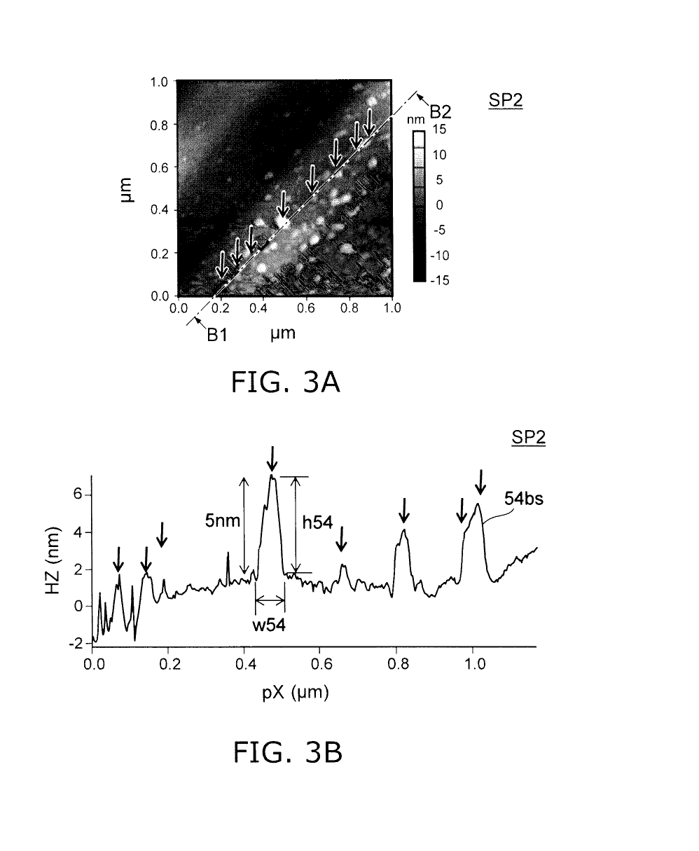

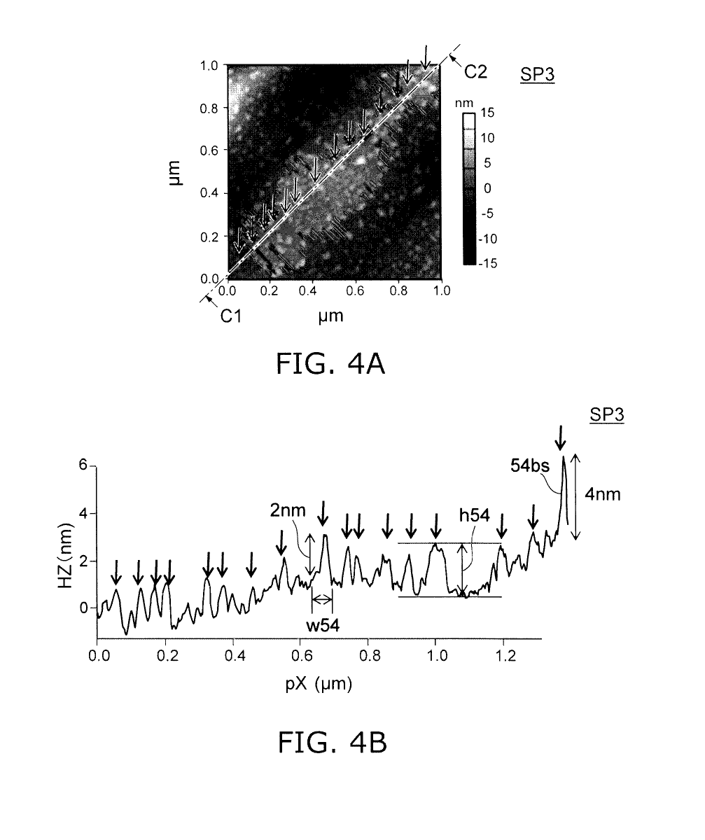

FIG. 3A, FIG. 3B, FIG. 4A, and FIG. 4B are schematic views showing the nitride semiconductor element.

FIG. 3A and FIG. 3B correspond to the second sample SP2. FIG. 4A and FIG. 4B correspond to the third sample SP3. FIG. 3A and FIG. 4A are AFM images of the front surface of the p-type contact layer 54. FIG. 3B and FIG. 4B are graphs of the configuration (the profile) of the front surface of the p-type contact layer 54 (the first surface 50s of the p-type semiconductor layer 50). FIG. 3B and FIG. 4B are obtained from the AFM analysis results of FIG. 3A and FIG. 4A.

FIG. 3B corresponds to the profile along line B1-B2 of FIG. 3A. Line B1-B2 is aligned with the c-axis direction of the p-type contact layer 54 and is aligned with the c-axis direction of the n-type semiconductor layer 20. The horizontal axis of FIG. 3B corresponds to a position pX along line B1-B2. FIG. 4B corresponds to the profile along line C1-C2 of FIG. 4A. Line C1-C2 is aligned with the c-axis direction of the p-type contact layer 54 and aligned with the c-axis direction of the n-type semiconductor layer 20. The horizontal axis of FIG. 4B corresponds to the position pX (μm) along line C1-C2. In FIG. 3B and FIG. 4B, the vertical axis is a height HZ (nm). The height HZ is the position along the Z-axis direction. The arrows inside FIG. 3B and FIG. 4B correspond to the protrusions 54b.

As shown in FIG. 3B and FIG. 4B, the height h54 of the protrusions 54b is not less than 0.3 nm and not more than 5 nm (not less than 1 nm and not more than 5 nm). The width w54 of the multiple protrusions 54b is about 50 nm (not less than about 10 nm and not more than about 100 nm).

FIG. 5 is a graph of a characteristic of the nitride semiconductor element.

In FIG. 5, the horizontal axis is a density Cp (/cm²) of the protrusions 54b. The vertical axis is the value of a drive voltage Vf (V). The drive voltage Vf is the voltage when a current of 1 mA is caused to flow.

As shown in FIG. 5, the drive voltage Vf of the first sample SP1 is about 5 V. The drive voltage Vf of the second sample SP2 is about 3.3 V. The drive voltage Vf of the third sample SP3 is about 3.5 V.

A low drive voltage Vf is obtained when the density Cp of the protrusions 54b exceeds 1.0×10¹⁰/cm². A low drive voltage Vf is obtained when the density Cp is 6.1×10¹⁰/cm² or less. An even lower drive voltage Vf is obtained when the density Cp of the protrusions 54b is 1.5×10¹⁰/cm² or more. An even lower drive voltage Vf is obtained when the density Cp is 5.2×10¹⁰/cm² or less.

Generally, the nitride semiconductor element is formed utilizing the c-plane of the nitride semiconductor. However, in the semiconductor layer using the c-plane, a large internal electric field is generated; and the characteristics of the element are affected. For higher performance of the element, the utilization of a crystal plane (e.g., a semi-polar plane or a non-polar plane) different from the c-plane is being investigated. However, for example, it was found that compared to the case where a polar plane (the c-plane) is used, the drive voltage easily becomes high in a nitride semiconductor element in which a semi-polar plane or a non-polar plane is utilized. Therefore, it is desirable to reduce the drive voltage in the nitride semiconductor element having the semi-polar plane or the non-polar plane.

In the embodiment, the multiple protrusions 54b are provided in the first surface 50s of the p-type semiconductor layer 50 contacting the p-side electrode 80 in a nitride semiconductor element using a semi-polar plane. The drive voltage Vf can be reduced by setting the density of the multiple protrusions 54b to be in the range recited above.

For example, there is a reference example that uses the c-plane ({0001}). For such a case, there is a reference example in which the multiple protrusions 54b are provided in the first surface 50s of the p-type semiconductor layer 50 contacting the p-side electrode 80. However, the appropriate density of the multiple protrusions 54b of the reference example is different from the appropriate density of the multiple protrusions 54b for a semi-polar plane.

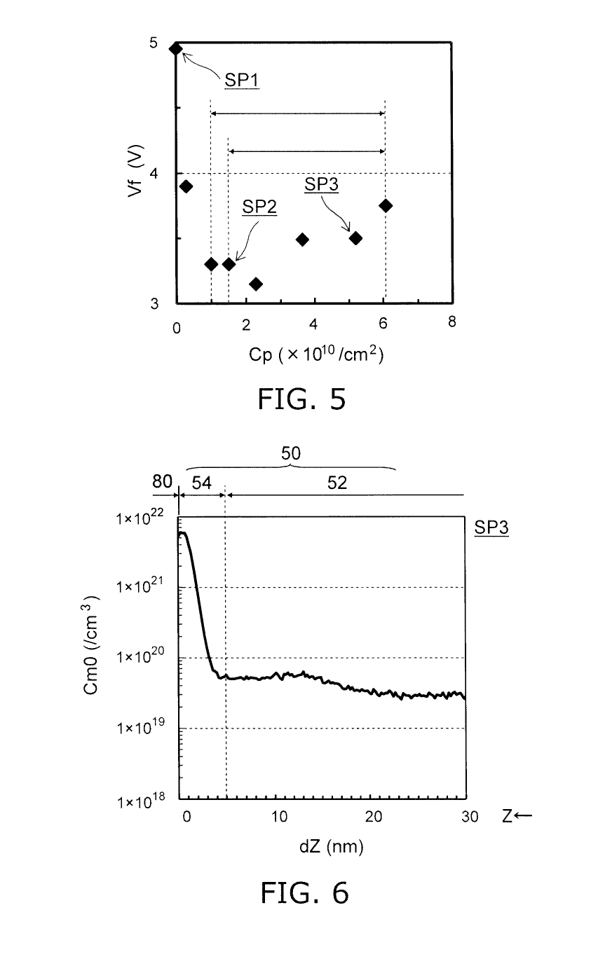

FIG. 6 is a graph of a characteristic of the nitride semiconductor element according to the first embodiment.

FIG. 6 shows the analysis results of secondary ion mass spectrometry (SIMS) of the third sample SP3. The horizontal axis is the depth dZ (nm). The depth dZ is the position along the Z-axis direction. The vertical axis is a concentration Cm0 (1/cm³) of Mg detected by the SIMS analysis. A Cs ion beam is used in the SIMS analysis. The measured surface area of the SIMS analysis is about 200 μm by 200 μm. The SIMS analysis is performed using a step of about 0.6 nm in the depth direction (the Z-axis direction). The average concentration of Mg for a region of about 200 μm by 200 μm by 0.6 nm is obtained in the analysis. For example, the average concentration of Mg for the protrusions 54b and the bottoms 54a is obtained. For example, the concentration Cm0 of Mg is substantially the average concentration in the surface.

In FIG. 6, there is a region where the Mg concentration changes abruptly from the front surface side (in the figure, the left side) and a region where the change is gradual. The region where the Mg concentration changes abruptly corresponds to the p-type contact layer 54. The region where the change is gradual corresponds to the second p-type layer 52. The change of the Mg concentration with respect to the change of the thickness of the p-type contact layer 54 is not less than 5 times the change of the Mg concentration with respect to the change of the thickness of the second p-type layer 52. In the example shown in FIG. 6, the region where the Mg concentration is more than 5.0×10¹⁹/cm³ corresponds to the p-type contact layer 54.

As shown in FIG. 6, the concentration Cm0 of Mg is high at the shallow position of the p-type contact layer 54; and the concentration Cm0 of Mg is low at the deep position. The maximum value of the concentration Cm0 of Mg of the p-type contact layer 54 is about 5.9×10²¹/cm³. The minimum value of the concentration Cm0 of Mg of the p-type contact layer 54 is 5.0×10¹⁹/cm³. The average concentration of Mg of the p-type contact layer 54 is calculated to be 3.0×10²¹/cm³. The average concentration of Mg of the p-type contact layer 54 is the value of the integral of the concentration Cm0 of Mg of the p-type contact layer 54 divided by the thickness (the depth) of the p-type contact layer 54.

Similarly to the third sample SP3, SIMS analysis is performed for the first sample SP1 and the second sample SP2. Similarly, samples other than these samples are made using different conditions; and SIMS analysis is performed.

In a first experiment as recited above, a sample is made in which the major surface of the foundation layer 19 is the {11-22} plane, and the first surface 50s of the p-type contact layer 54 is the {11-22} plane. In the first experiment, the concentration of Mg of the p-type contact layer 54 is modified as recited above.

In a second experiment, a sample is made in which the major surface of the foundation layer 19 is the {0001} plane, and the first surface 50s of the p-type contact layer 54 is the {0001} plane. The concentration of Mg of the p-type contact layer 54 is modified in the second experiment as well.

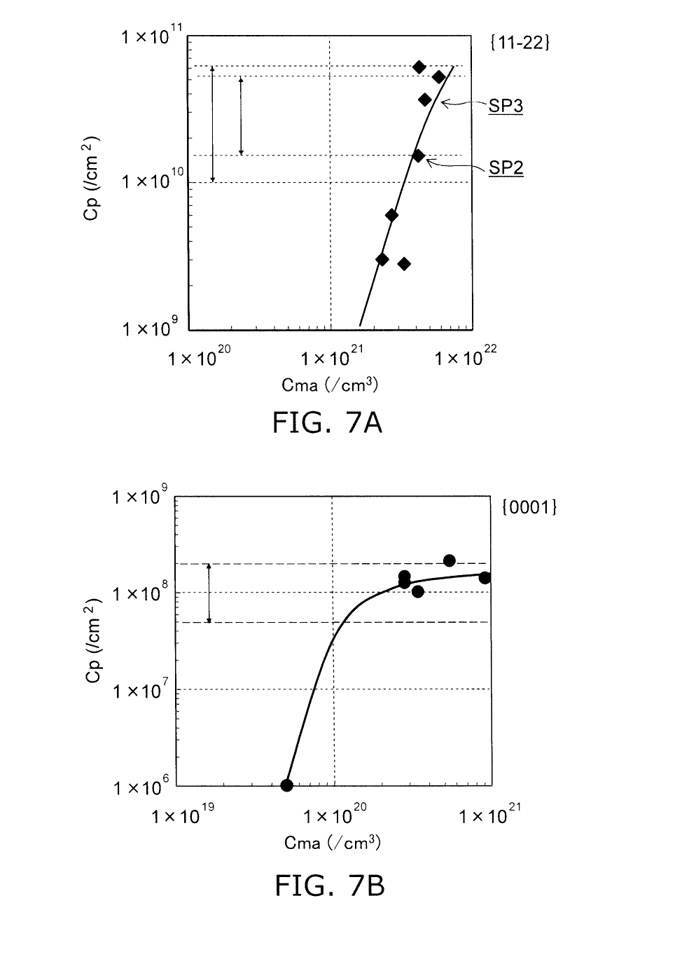

FIG. 7A and FIG. 7B are graphs of characteristics of the nitride semiconductor element.

FIG. 7A and FIG. 7B show the relationship between a concentration Cma (/cm³) of Mg and the density Cp (/cm²) of the protrusions 54b of the p-type contact layer 54.

FIG. 7A corresponds to the first experiment ({11-22}). FIG. 7B corresponds to the second experiment ({0001}).

As described above in regard to FIG. 6, the concentration Cm0 of Mg of the p-type contact layer 54 corresponds to the average concentration in the surface of the Mg of the p-type contact layer 54 (specifically, the concentration of the region of about 200 μm by 200 μm by 0.6 nm). As shown in FIG. 6, the Mg concentration of the p-type contact layer 54 changes along the thickness direction inside the p-type contact layer 54. The concentration Cma of Mg of the p-type contact layer 54 is the maximum value of the concentration Cm0 of the p-type contact layer 54 (in the example of FIG. 6, about 5.9×10²¹/cm³). In other words, the concentration Cma of Mg of the p-type contact layer 54 is the concentration of Mg of at least a portion of the p-type contact layer 54.

In the first experiment as shown in FIG. 7A, the density Cp of the protrusions 54b increases as the concentration (the concentration Cma) of Mg of the p-type contact layer 54 increases. The density Cp of the protrusions 54b is 0 when the concentration Cma of Mg is less than 1.0×10²¹/cm³. In other words, the protrusions 54b are not formed. The protrusions 54b are formed when the concentration Cma of Mg is 1.0×10²¹/cm³ or more. In the case of the {11-22} plane, the density of the protrusions 54b is about 3×10⁹/cm² to 7×10¹⁰/cm². The density of the protrusions 54b is high for the {11-22} plane.

In the second experiment as shown in FIG. 7B, the density Cp of the protrusions 54b increases as the concentration (the concentration Cma) of Mg of the p-type contact layer 54 increases. However, the density Cp of the protrusions 54b is substantially constant when the concentration Cma of Mg is 2.0×10²¹/cm³ or more. The density Cp of the protrusions 54b saturates at about 2.0×10⁸/cm². It is difficult to obtain a high density of the protrusions 54b for the {0001} plane.

As described above in regard to FIG. 5, a low drive voltage Vf is obtained when the density Cp of the protrusions 54b is more than 1.0×10¹⁰/cm² and not more than 6.1×10¹⁰/cm². An even lower drive voltage Vf is obtained when the density Cp of the protrusions 54b is not less than 1.5×10¹⁰/cm² and not more than 5.2×10¹⁰/cm². These results plus the results shown in FIG. 7A give the following results. A low drive voltage Vf is obtained when the concentration Cma of Mg of the p-type contact layer 54 is more than 3.2×10²¹/cm³ and not more than 7.0×10²¹/cm³. A low drive voltage Vf is obtained stably when the concentration Cma of Mg of the p-type contact layer 54 is not less than 4.0×10²¹/cm³ and not more than 5.5×10²¹/cm³.

In the reference example (the second experiment of the {0001} plane) shown in FIG. 7B, the maximum value of the density Cp of the protrusions 54b is about 2.0×10⁸/cm² as recited above. This is different from the range (3×10⁹/cm² to 7×10¹⁰/cm²) of the embodiment. Also, in the reference example (the second experiment of the {0001} plane), the concentration Cma of Mg is 1×10²¹/cm³ or less. For example, it is realistically difficult to set the concentration Cma of Mg to be higher than 1×10²¹/cm³ in the reference example (the second experiment of the {0001} plane). In other words, for example, the crystal quality degrades markedly when the concentration Cma of Mg is set to be higher than 1×10²¹/cm³.

Conversely, the density of the protrusions 54b can be set to be about 3×10⁹/cm² to 7×10¹⁰/cm² in the embodiment (the {11-22} plane which is a semi-polar plane). The concentration Cma of Mg can be set to be 3.2×10²¹/cm³ or more. It is considered that this is because the agglomeration of Mg does not occur easily in the semi-polar plane (the {11-22} plane) compared to the polar plane (the {0001} plane).

It is considered that this is because degradation of the crystal quality caused by Mg does not occur easily in the semi-polar plane (e.g., the {11-22} plane) compared to the polar plane (the {0001} plane). In the polar plane (the {0001} plane), gallium (group III atoms) easily exists as the atoms of the outermost surface of the crystal. On the other hand, in the semi-polar plane (the {11-22} plane), atoms of both gallium (group III atoms) and nitrogen (group V atoms) exist at the outermost surface of the crystal. It is considered that the incorporation of the p-type impurity (Mg) changes due to such a difference of the configuration of the atoms of the crystal surface (the arrangement of the atoms of the crystal plane). It is considered that the ease of the surface diffusion of the p-type impurity atoms changes due to such a difference of the configuration of the atoms of the crystal surface.

In the semi-polar plane, it is considered that the surface diffusion length of the Mg atoms in the crystal surface increases easily; and the agglomeration of Mg does not occur easily. Therefore, a high density of the protrusions 54b can be obtained.

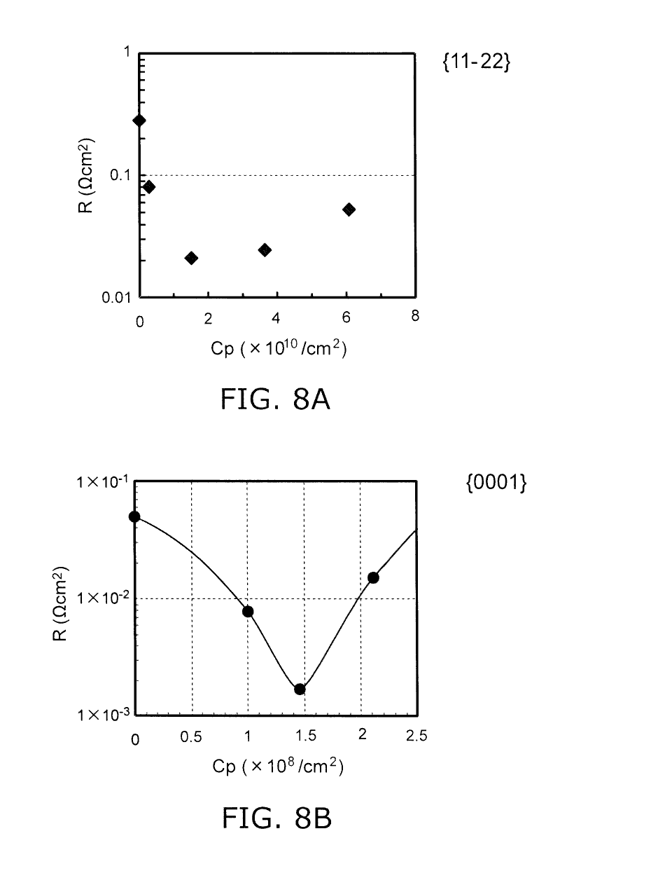

FIG. 8A and FIG. 8B are graphs of characteristics of the nitride semiconductor element.

FIG. 8A and FIG. 8B show the relationship between the density Cp (/cm²) of the protrusions 54b and a contact resistance R (Ωcm²). The contact resistance R (Ωcm²) is the contact resistance between the p-type contact layer 54 and the p-side electrode 80. FIG. 8A corresponds to the first experiment (the {11-22} plane). FIG. 8B corresponds to the second experiment (the {0001} plane).

In the first experiment (the {11-22} plane) as shown in FIG. 8A, a low contact resistance R is obtained when the density Cp (/cm²) of the protrusions 54b is more than 1.0×10¹⁰/cm² and not more than 6.1×10¹⁰/cm².

In the second experiment (the {0001} plane) as shown in FIG. 8B, a relatively low contact resistance R is obtained when the density Cp (/cm²) of the protrusions 54b is not less than 1.0×10⁸/cm² and not more than 2.1×10⁸/cm².

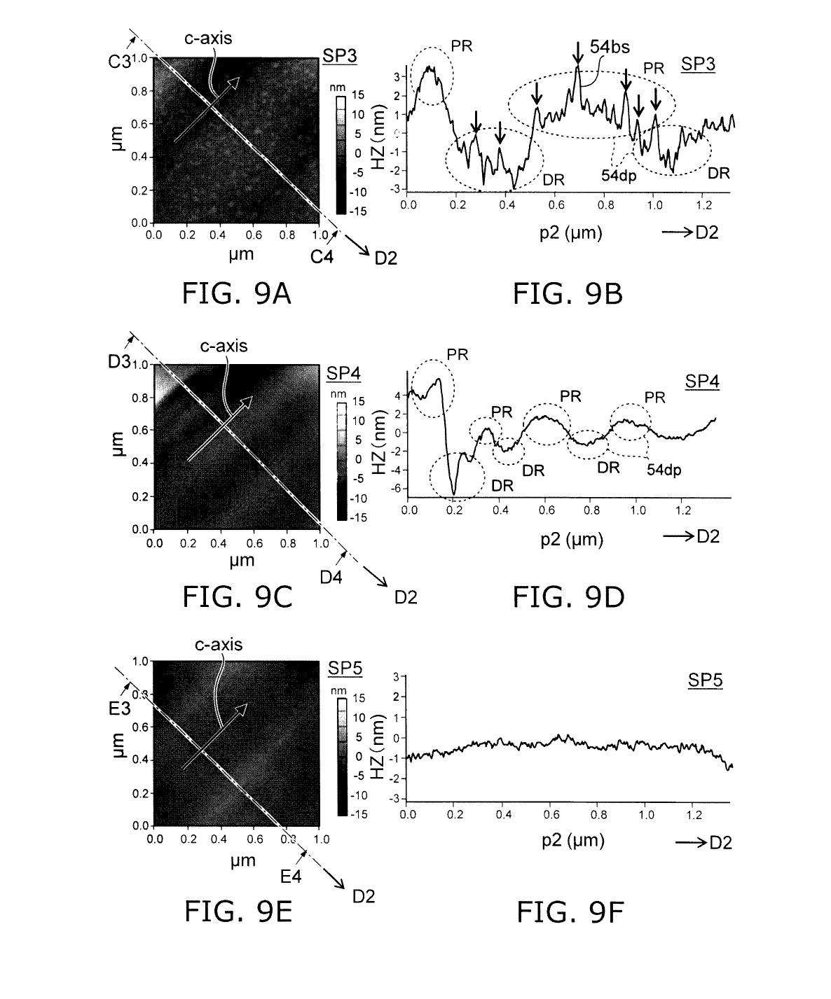

FIG. 9A to FIG. 9F are schematic views showing the nitride semiconductor element.

FIG. 9A and FIG. 9B correspond to the third sample SP3.

FIG. 9C and FIG. 9D correspond to a fourth sample SP4.

FIG. 9E and FIG. 9F correspond to a fifth sample SP5.

FIG. 9A, FIG. 9C, and FIG. 9E are AFM images of the front surface of the p-type contact layer 54.

FIG. 9B, FIG. 9D, and FIG. 9F are graphs of the profile of the front surface of the p-type contact layer 54 (the first surface 50s of the p-type semiconductor layer 50).

FIG. 9B, FIG. 9D, and FIG. 9F are obtained from the AFM analysis results of FIG. 9A, FIG. 9C, and FIG. 9E.

FIG. 9B corresponds to the profile along line C3-C4 of FIG. 9A. Line C3-C4 is perpendicular to the c-axis direction of the p-type contact layer 54 and perpendicular to the c-axis direction of the n-type semiconductor layer 20. For example, a direction perpendicular to the first direction (the Z-axis direction) and perpendicular to the c-axis direction is taken as a second direction D2. The horizontal axis of FIG. 9B corresponds to a position p2 along line C3-C4 (along the second direction D2).

FIG. 9D corresponds to the profile along line D3-D4 of FIG. 9C. Line D3-D4 is perpendicular to the c-axis direction of the p-type contact layer 54 and perpendicular to the c-axis direction of the n-type semiconductor layer 20. The horizontal axis of FIG. 9D corresponds to the position p2 along line D3-D4 (along the second direction D2).

FIG. 9F corresponds to the profile along line E3-E4 of FIG. 9E. Line E3-E4 is perpendicular to the c-axis direction of the p-type contact layer 54 and perpendicular to the c-axis direction of the n-type semiconductor layer 20. The horizontal axis of FIG. 9F corresponds to the position p2 along line E3-E4 (along the second direction D2).

In FIG. 9B, FIG. 9D, and FIG. 9F, the vertical axis is the height HZ (nm). The height HZ is the position along the Z-axis direction. The arrows inside FIG. 9B correspond to the protrusions 54b.

For the fourth sample SP4, the supply of the ammonia when forming the p-type GaN layer used to form the second p-type layer 52 is ½ of that of the third sample SP3. For the fourth sample SP4, the supply amounts of TMG and Cp₂Mg are the same as those of the third sample SP3. For the fourth sample SP4, the supply amount of the p-type impurity when forming the p-type GaN layer used to form the p-type contact layer 54 is ⅙ of that of the third sample SP3.

For the fifth sample SP5, the supply of the ammonia when forming the second p-type layer 52 is ¼ of that of the third sample SP3. For the fifth sample SP5, the supply amounts of TMG and Cp₂Mg are the same as those of the fourth sample SP4. For the fifth sample SP5, the supply amount of the p-type impurity when forming the p-type GaN layer used to form the p-type contact layer 54 is ⅙ of that of the third sample SP3.

The multiple protrusions 54b are provided in the third sample SP3 as shown in FIG. 9B. Also, an unevenness 54dp exists. In other words, the first surface 50s includes the unevenness 54dp. The size of the unevenness 54dp is larger than the size of the protrusions 54b. The distance between the unevenness 54dp is longer than the distance between the multiple protrusions 54b. The height of the unevenness 54dp is higher than the height of the protrusions 54b. The unevenness 54dp includes a protrusion region PR and a recess region DR. The protrusion region PR extends along a plane including the c-axis direction of the n-type semiconductor layer 20 (the c-axis direction of the p-type contact layer 54). The recess region DR extends along the plane including the c-axis direction.

The height of the unevenness 54dp is higher than 5 nm. The height of the unevenness 54dp is 100 nm or less. It is more favorable for the height of the unevenness 54dp to be not less than 10 nm and not more than 60 nm. The height of the unevenness 54dp is the distance along the Z-axis direction between the top region of the protrusion region PR and the bottom region of the recess region DR.

The width of the unevenness 54dp is, for example, not less than about 80 nm and not more than about 1500 nm. It is more favorable for the width of the unevenness 54dp to be not less than 200 nm and not more than 900 nm. It is more favorable for the width of the unevenness 54dp to be not less than 250 nm and not more than 500 nm. The distance between the multiple protrusion regions PR (the width of one recess region DR) is, for example, not less than about 80 nm and not more than about 1500 nm. It is more favorable for the distance between the multiple protrusion regions PR to be not less than 200 nm and not more than 900 nm. It is more favorable for the distance between the multiple protrusion regions PR to be not less than 250 nm and not more than 500 nm. The distance between the multiple recess regions DR (the width of one protrusion region PR) is, for example, not less than about 80 nm and not more than about 1500 nm. It is more favorable for the distance between the multiple recess regions DR (the width of one protrusion region PR) to be not less than 200 nm and not more than 900 nm. It is more favorable for the distance between the multiple recess regions DR (the width of one protrusion region PR) to be not less than 250 nm and not more than 500 nm.

For example, the width of the protrusion region PR in the second direction D2 is not less than 80 nm and not more than 1500 nm. More favorably, the width in the second direction of the protrusion region PR is not less than 200 nm and not more than 900 nm. It is more favorable for the width in the second direction of the protrusion region PR to be not less than 250 nm and not more than 500 nm. The width of the recess region DR in the second direction D2 is not less than 80 nm and not more than 1500 nm. More favorably, the width in the second direction D2 of the recess region DR may be not less than 200 nm and not more than 900 nm. It is more favorable for the width in the second direction D2 of the recess region DR to be not less than 250 nm and not more than 500 nm.

As described above, the drive voltage Vf (the voltage when the current is 1 mA) of such a third sample SP3 is about 3.5 V.

As shown in FIG. 9D, the multiple protrusions 54b are not provided in the fourth sample SP4. However, the unevenness 54dp that includes the protrusion region PR and the recess region DR is provided in the fourth sample SP4. The drive voltage Vf (the voltage when the current is 1 mA) of such a fourth sample SP4 is about 4.7 V.

In the fifth sample SP5 as shown in FIG. 9F, the multiple protrusions 54b are not provided; and the unevenness 54dp that includes the protrusion region PR and the recess region DR is not provided. The drive voltage Vf (the voltage when the current is 1 mA) of such a fifth sample SP5 is about 5.5 V.

Thus, it can be seen that the drive voltage Vf is reduced by providing an unevenness 54dp such as that recited above. Accordingly, it is more desirable to provide both the unevenness 54dp and the protrusions 54b in the embodiment.

Similar investigations also were performed for the {10-11} plane which is the semi-polar plane.

The base body that is used to form the substrate 10 includes a silicon substrate of the {001} plane. Otherwise, the samples are made by a method similar to that of the {11-22} plane described above. In the samples, the major surface of the foundation layer 19 is {10-11}; and the first surface 50s of the p-type contact layer 54 is {10-11}.

In the silicon substrate that is used, the {001} plane is rotated about 8 degrees in the <110> axis direction from the <001> axis. In the plane including the <001> axis, the angle between the Si {001} plane and the upper surface 10u of the substrate 10 is about 8 degrees. In the silicon substrate that is used, the {001} plane is tilted about 8 degrees toward the <110> direction. The extension direction of the recess 15 (e.g., the stripe configuration) is aligned with the <−110> direction.

The following three types of samples are made.

In a seventh sample SP7, the concentration (the concentration Cma) of Mg of the p-type contact layer 54 is 8×10²⁰/cm³; and the multiple protrusions 54b are not provided.

In an eighth sample SP8, the concentration (the concentration Cma) of Mg of the p-type contact layer 54 is 3×10²¹/cm³; and the density of the protrusions 54b is 1×10¹⁰/cm².

In a ninth sample SP9, the concentration (the concentration Cma) of Mg of the p-type contact layer 54 is 5×10²¹/cm³; and the density of the protrusions 54b is 3×10¹⁰/cm².

In these samples, the voltage when a current of 1 mA is caused to flow is 4.5 V, 3.4 V, and 3.5 V respectively for the seventh to ninth samples SP7, SP8, and SP9.

The supply of the ammonia when forming the p-type GaN layer used to form the second p-type layer 52 of a tenth sample SP10 is 3 times that of the ninth sample SP9. The unevenness 54dp that includes the protrusion region PR and the recess region DR is provided in the tenth sample SP10. The voltage when a current of 1 mA is caused to flow in the tenth sample SP10 is 3.1 V.

For the semi-polar {10-11} plane as well, a low drive voltage Vf is obtained when the density Cp of the protrusions 54b is more than 1.0×10¹⁰/cm². A low drive voltage Vf is obtained when the density Cp of the protrusions 54b is 6.1×10¹⁰/cm² or less. An even lower drive voltage Vf is obtained by providing both the unevenness 54dp and the protrusions 54b.

In the {10-11} plane, the atoms of the outermost surface of the crystal are nitrogen (group V atoms). On the other hand, in the polar plane (the {0001} plane), gallium (group III atoms) exist easily in the outermost surface of the crystal. Thus, the {10-11} plane and the {0001} plane are different. Therefore, it is considered that the effect of lowering drive voltage due to the protrusions 54b is obtained easily in the semi-polar plane where the nitrogen atoms (the group V atoms) appear in the front surface.

For example, a low drive voltage Vf is obtained when the protrusions 54b are provided in the p-type contact layer 54 in the semi-polar plane including nitrogen atoms (group V atoms) in the outermost surface of the crystal (the atomic arrangement of the crystal plane) and the density Cp of the protrusions is more than 1.0×10¹⁰/cm² and not more than 6.1×10¹⁰/cm².

There is a configuration in which the light extraction efficiency is increased by providing an unevenness in the semiconductor layer to change the optical path of the emitted light. For example, there is a method for forming protrusions in the semiconductor layer by selective growth. In such a case, the height of the protrusions is about 1.5 μm. Also, there is a configuration in which a polarity inversion layer that includes an unevenness formed by wet etching is used as the semiconductor layer. In such a case, it is desirable for the thickness of the polarity inversion layer to be 0.1 μm or more (more desirably, 0.3 μm or more).

Thus, in the case where the optical path of the emitted light is changed by an unevenness, the size of the unevenness that is used is about the wavelength of the emitted light. An unevenness that is markedly smaller than the wavelength of the emitted light substantially does not change the optical path of the emitted light. For example, the effect of changing the optical path is small in the case where the size of the unevenness is not more than ¼ of the wavelength of the emitted light.

In the semiconductor light emitting element 110 according to the embodiment, the height (the height h54) along the Z-axis direction of the multiple protrusions 54b is less than the length of ¼ of the dominant wavelength of the light emitted from the light emitting layer 40. In the embodiment, the effect of changing the optical path is obtained not by using the protrusions 54b but by, for example, reducing the contact resistance R. In the embodiment, for example, the drive voltage is reduced by the protrusions 54b.

For the silicon substrate of the {001} plane in the embodiment, the angle of the tilt of the Si {001} plane from the <001> axis toward the <110> axis direction is not limited to 8 degrees. The angle of the tilt may be, for example, not less than 5 degrees and not more than 11 degrees. For example, a silicon substrate having a crystal plane tilted at an angle within 3 degrees in any direction from the Si {001} plane may be used.

In the embodiment, the first surface 50s may be tilted at a small angle with respect to the {10-11} plane. For example, the angle between the first surface 50s and the {10-11} plane of the p-type semiconductor layer 50 is 5 degrees or less.

The method for depositing the nitride semiconductor layer in the method for manufacturing the nitride semiconductor element according to the embodiment may include, for example, metal-organic chemical vapor deposition (MOCVD), metal-organic vapor phase epitaxy (MOVPE), molecular beam epitaxy (MBE), hydride vapor phase epitaxy (HVPE), etc.

According to the embodiments, a nitride semiconductor element can be provided in which the drive voltage can be reduced.

In the specification, “nitride semiconductor” includes all compositions of semiconductors of the chemical formula BₓIn_{y}Al_{z}Ga_{1-x-y-z}N (0≦x≦1, 0≦y≦1, 0≦z≦1, and x+y+z≦1) for which the composition ratios x, y, and z are changed within the ranges respectively. “Nitride semiconductor” further includes group V elements other than N (nitrogen) in the chemical formula recited above, various elements added to control various properties such as the conductivity type and the like, and various elements included unintentionally.

In the specification of the application, “perpendicular” and “parallel” include not only strictly perpendicular and strictly parallel but also, for example, the fluctuation due to manufacturing processes, etc.; and it is sufficient to be substantially perpendicular and substantially parallel.

Hereinabove, embodiments of the invention are described with reference to specific examples. However, the invention is not limited to these specific examples. For example, one skilled in the art may similarly practice the invention by appropriately selecting specific configurations of components included in the nitride semiconductor element such as the p-type semiconductor layer, the n-type semiconductor layer, the light emitting layer, the foundation layer, the buffer layer, the substrate, the p-side electrode, the n-side electrode, etc., from known art; and such practice is within the scope of the invention to the extent that similar effects can be obtained.

Further, any two or more components of the specific examples may be combined within the extent of technical feasibility and are included in the scope of the invention to the extent that the purport of the invention is included.

Moreover, all nitride semiconductor elements practicable by an appropriate design modification by one skilled in the art based on the nitride semiconductor elements described above as embodiments of the invention also are within the scope of the invention to the extent that the spirit of the invention is included. Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nitride semiconductor element, comprising:
a p-type semiconductor layer including a nitride semiconductor, the p-type semiconductor layer having a first surface; and
a p-side electrode contacting the first surface,
the first surface being a semi-polar plane,
the first surface including a plurality of protrusions,
a height of the protrusions along a first direction being not less than 1 nanometer and not more than 5 nanometers, the first direction being from the p-type semiconductor layer toward the p-side electrode,
a density of the protrusions in the first surface being more than 1.0×10¹⁰/cm² and not more than 6.1×10¹⁰/cm².

2. The element according to claim 1, wherein the first surface is a {11-22} plane of the p-type semiconductor layer.

3. The element according to claim 1, wherein an angle between the first surface and the {11-22} plane of the p-type semiconductor layer is 5 degrees or less.

4. The element according to claim 1, wherein the first surface is a {10-11} plane of the p-type semiconductor layer.

5. The element according to claim 1, wherein an angle between the first surface and the {10-11} plane of the p-type semiconductor layer is 5 degrees or less.

6. The element according to claim 1, wherein a width in a direction perpendicular to the first direction of one of the protrusions is not less than 10 nanometers and not more than 100 nanometers.

7. The element according to claim 1, further comprising:
an n-type semiconductor layer; and
a light emitting layer,
the p-type semiconductor layer being provided between the n-type semiconductor layer and the p-side electrode,
the light emitting layer being provided between the n-type semiconductor layer and the p-type semiconductor layer.

8. The element according to claim 1, wherein the density of the protrusions in the first surface is 1.5×10¹⁰/cm² or more.

9. The element according to claim 8, wherein the density of the protrusions in the first surface is 5.2×10¹⁰/cm² or less.

10. The element according to claim 1, wherein
the p-type semiconductor layer includes a p-type contact layer,
the p-type contact layer contacts the second electrode,
a thickness of the p-type contact layer is not less than 1 nanometer and not more than 50 nanometers, and
a concentration of a p-type impurity included in the p-type contact layer is more than 3.2×10²¹/cm³ and not more than 7.0×10²¹/cm³.

11. The element according to claim 10, wherein the concentration is not less than 4.0×10²¹/cm³ and not more than 5.5×10²¹/cm³.

12. The element according to claim 1, wherein
the first surface includes an unevenness,
the unevenness includes a protrusion region and a recess region,
the protrusion region extends along a plane including the c-axis direction of the n-type semiconductor layer,
the recess region extends along the plane including the c-axis direction, and
a width of the protrusion region in a second direction is not less than 80 nanometers and not more than 1500 nanometers, the second direction being perpendicular to the first direction and perpendicular to the c-axis direction.

13. The element according to claim 12, wherein the width of the protrusion region is not less than 200 nanometers and not more than 900 nanometers.

14. The element according to claim 12, wherein a width of the recess region in the second direction is not less than 80 nanometers and not more than 1500 nanometers.

15. The element according to claim 14, wherein the width of the recess region is not less than 200 nanometers and not more than 900 nanometers.

16. The element according to claim 12, wherein a height of the unevenness is more than 5 nanometers.
